(19) United States
(12) Patent Application Publication
(10) Pub. No.: US 2022/0276308 A1
(43) Pub. Date: Sep. 1, 2022

(54) CURRENT SENSOR

(71) Applicant: Yazaki Corporation, Tokyo (JP)

(72) Inventors: Yasunori Kawaguchi, Shizuoka (JP); Yoshiyuki Mizuno, Shizuoka (JP)

(21) Appl. No.: 17/676,232

(22) Filed: Feb. 21, 2022

(30) Foreign Application Priority Data
Feb. 26, 2021 (JP) 2021-029707
Jul. 7, 2021 (JP) 2021-112470

(51) Int. Cl. G01R 31/364; G01R 19/00; H01C 1/148; G01R 1/20; H01R 11/28

(52) U.S. Cl. CPC G01R 31/364; G01R 19/0092; H01C 1/148; G01R 1/203; H01R 11/281

(57) ABSTRACT

A current sensor includes a pair of bus bars, a shunt resistor conductively connected between the pair of bus bars, and a housing in which the shunt resistor is built. The shunt resistor includes a body part interposed between the pair of bus bars and detection terminal parts for current detection. Each of the detection terminal parts includes a body connection portion that is connected to the body part, a tip end connection portion that is exposed from the housing and extends along a first direction, and an intermediate portion that is interposed between the body connection portion and the tip end connection portion and extends by protruding from the tip end connection portion along a second direction.

### CROSS-REFERENCE TO RELATED APPLICATION(S)

The present application claims priority to and incorporates by reference the entire contents of Japanese Patent Application No. 2021-029707 filed in Japan on Feb. 26, 2021 and Japanese Patent Application No. 2021-112470 filed in Japan on Jul. 7, 2021.

### BACKGROUND OF THE INVENTION

### 1. Field of the Invention

The present invention relates to a current sensor.

### 2. Description of the Related Art

As a technology related to a current sensor in the related art, for example, Japanese Patent Application Laid-open No. 2020-193845 discloses a sensor having a first bus bar, a second bus bar, and a shunt resistor. The shunt resistor includes a shunt resistor body part whose one end part is joined to the first bus bar and the other end part is joined to the second bus bar, and a detection terminal extending from the shunt resistor body part.

However, in such a current sensor, for example, there is a case where the shunt resistor is built in a housing having an insulating property. Furthermore, the current sensor has room for further improvement in the configuration in which the shunt resistor is built in the housing.

### SUMMARY OF THE INVENTION

The present invention has been made in view of the afore-mentioned circumstances, and an object of the present invention to provide a current sensor capable of appropriately implementing a configuration in which a shunt resistor is built in a housing.

In order to achieve the above mentioned object, a current sensor according to one aspect of the present invention includes a pair of bus bars having conductivity; a shunt resistor conductively connected between the pair of bus bars; and a housing having an insulating property and in which the shunt resistor is built, wherein the shunt resistor includes a body part interposed between the pair of bus bars and a detection terminal part for current detection that protrude from the body part, and the detection terminal part includes a body connection portion that is connected to the body part, a tip end connection portion that is exposed from the housing and extends along a first direction, and an intermediate portion that is interposed between the body connection portion and the tip end connection portion and extends by protruding from the tip end connection portion along a second direction intersecting the first direction.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a circuit diagram illustrating a schematic configuration of a current sensor according to an embodiment;

FIG. 2 is a perspective view illustrating the schematic configuration of the current sensor according to the embodiment;

FIG. 3 is a perspective view illustrating the schematic configuration of the current sensor according to the embodiment;

FIG. 4 is an exploded perspective view illustrating the schematic configuration of the current sensor according to the embodiment;

FIG. 5 is a perspective view illustrating a schematic configuration of a bus bar assembly of the current sensor according to the embodiment;

FIG. 6 is a perspective view illustrating a schematic configuration of a shunt resistor of the current sensor according to the embodiment;

FIG. 7 is a partial cross-sectional view illustrating the schematic configuration of the current sensor according to the embodiment;

FIG. 8 is a partial cross-sectional view illustrating the schematic configuration of the current sensor according to the embodiment;

FIG. 9 is a partially exploded perspective view illustrating the schematic configuration of the current sensor according to the embodiment;

FIG. 10 is a partial front view illustrating a schematic configuration of a shunt resistor of a current sensor according to a modification;

FIG. 11 is a partial front view illustrating a schematic configuration of a shunt resistor of a current sensor according to a modification;

FIG. 12 is a partial cross-sectional view illustrating a schematic configuration of a current sensor according to a reference example; and

FIG. 13 is a partially exploded perspective view illustrating the schematic configuration of the current sensor according to the reference example.

### DETAILED DESCRIPTION OF THE PREFERRED EMBODIMENTS

Embodiments according to the present invention are described in detail with reference to the drawings. The present invention is not limited by the embodiments. Furthermore, components in the following embodiments include those that can be easily replaced by those skilled in the art or those that are substantially the same.

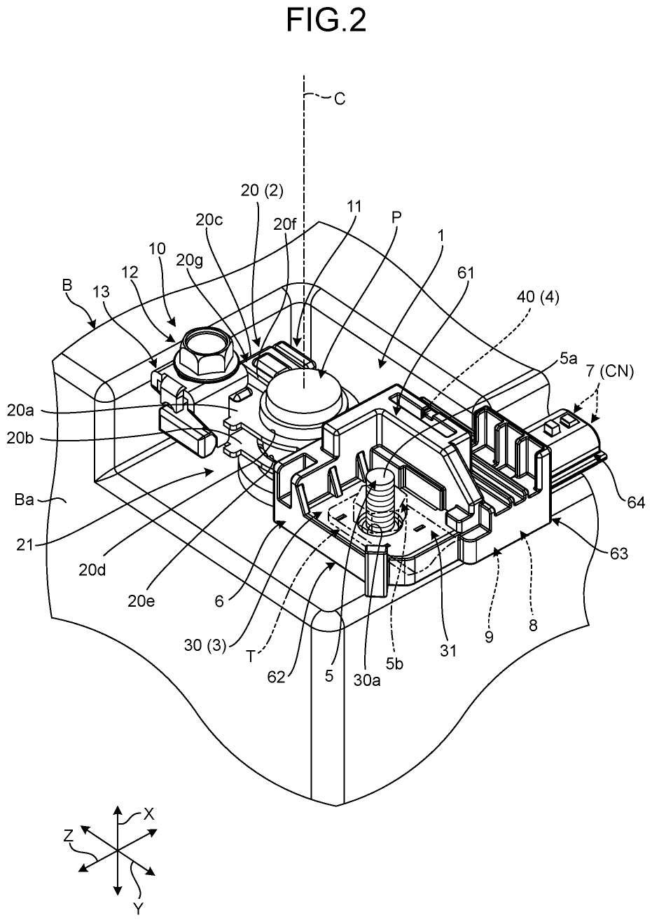

In the following description, among a first direction, a second direction, and a third direction that intersect each other, the first direction is referred to as an “axial direction X”, the second direction is referred to as a “first width direction Y”, and the third direction is referred to as a “second width direction Z”. The axial direction X, the first width direction Y, and the second width direction Z are substantially orthogonal to each other. The axial direction X typically corresponds to a direction along a central axis C (see FIG. 2 and the like) of a battery post provided with a current sensor, a height direction of a battery, and the like. The first width direction Y typically corresponds to a direction in which a battery terminal unit and a sensor unit are juxtaposed, and the like. The second width direction Z typically corresponds to a tightening direction of the battery terminal unit, and the like. Typically, in a state in which the current sensor is installed in a vehicle and the vehicle is located in a horizontal plane, the axial direction X is along a vertical direction, and the first width direction Y and the second width direction Z are along a horizontal direction. It is assumed that respective directions used in the following description represent directions in a state in which units are assembled to each other, unless otherwise specified.

### Embodiment

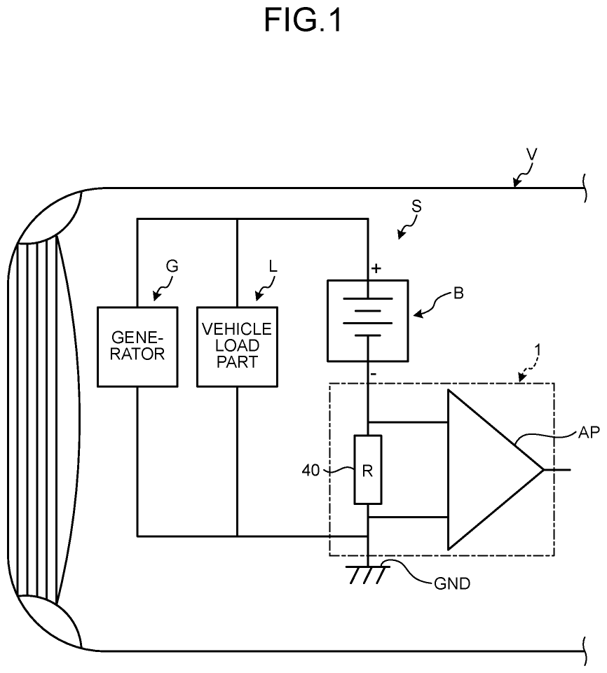

A current sensor 1 of the present embodiment illustrated in FIG. 1 and FIG. 2 is a sensor for measuring the charge/discharge current of a battery B mounted in a vehicle V. In a power supply system S of the vehicle V including the battery B, in recent years, the consumption of the battery B tends to increase relatively with an increase and the like in the type and number of electrical components of the vehicle V, and there is a demand for more appropriate monitoring of the state of the battery B in order to respond to such a tendency. In order to meet such a demand, the power supply system S detects the charge/discharge current of the battery B by the current sensor 1, and performs monitoring of the remaining capacity of the battery B, detection of the consumption (degree of deterioration) of the battery B, fuel efficiency improvement processing through operation control of a generator G such as an alternator, and the like, on the basis of the detected current (current value).

The current sensor 1 of the present embodiment is configured to have a battery mounting structure, and constitutes a battery terminal integrated sensor integrated with a battery terminal (battery terminal unit 2). The battery B is mounted in the vehicle V as a power storage device. The battery B has a battery post P vertically installed on one surface of a battery housing Ba for accommodating battery fluid and various components, typically, a surface located on an upper side in the vertical direction. The battery post P is disposed so that the central axis C is along the vertical direction, here, the axial direction X, and extends in a columnar shape along the axial direction X. A total of two battery posts P are provided in one battery B, wherein one of the two battery posts P is a positive electrode (plus (+) electrode) and the other one is a negative electrode (minus (−) electrode) (only one is illustrated in FIG. 2 and the like).

The current sensor 1 that constitutes the battery terminal integrated sensor is fastened to the battery post P configured as described above. The current sensor 1 of the present embodiment is provided to the battery post P on the negative electrode side of the battery B, is interposed between the battery B and the generator G, a vehicle load part L, a ground part (vehicle body and the like) GND, and the like, and detects a current flowing between the battery post P and them. The current sensor 1 is fastened to the battery post P on the negative electrode side and electrically connected to the battery post P, and is electrically connected to a connection terminal T provided at the end of an electric wire (for example, an earth wire) on the ground part GND side. Furthermore, the current sensor 1 is interposed between the connection terminal T and the battery post P, electrically connects them to each other, and then detects a current flowing between the connection terminal T and the battery post P.

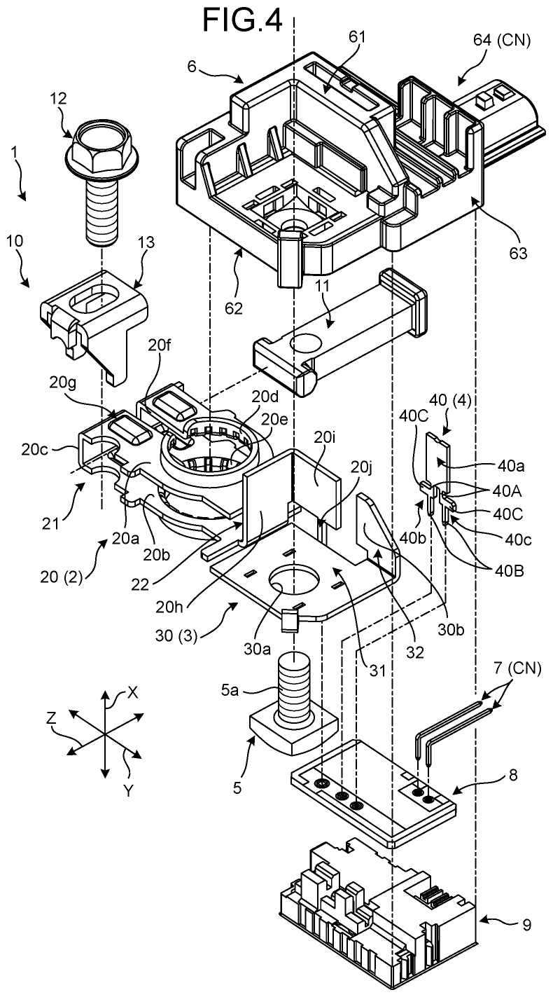

The current sensor 1 of the present embodiment is what is called a shunt-type current sensor. That is, the current sensor 1 passes a current to a shunt resistor 40 (see also FIG. 4 and the like), and measures a current value from a voltage drop when energized and a resistance value of the shunt resistor 40 by using Ohm's law. The current sensor 1 typically amplifies a voltage (detection voltage) generated across the shunt resistor 40 by an amplifier AP according to the current flowing through the shunt resistor 40, outputs the amplified voltage, and detects the current flowing through the shunt resistor 40 on the basis of the output of the amplifier AP. For example, compared to a magnetic detection-type current sensor using what is called a Hall IC or the like, the shunt-type current sensor 1 has advantages such as a wide selection range of electronic components, flexible support for high accuracy and low price, good temperature characteristics obtained by using an alloy with a low temperature change of a resistance value as the shunt resistor 40, little influence of an external magnetic field, no need for core shield plates, and lightweight.

Furthermore, the current sensor 1 of the present embodiment adds a predetermined shape to the shunt resistor 40 in a configuration in which a part of the shunt resistor 40 is built in a housing 6, thereby appropriately implementing the configuration. Hereinafter, components of the current sensor 1 are described in detail with reference to the drawings.

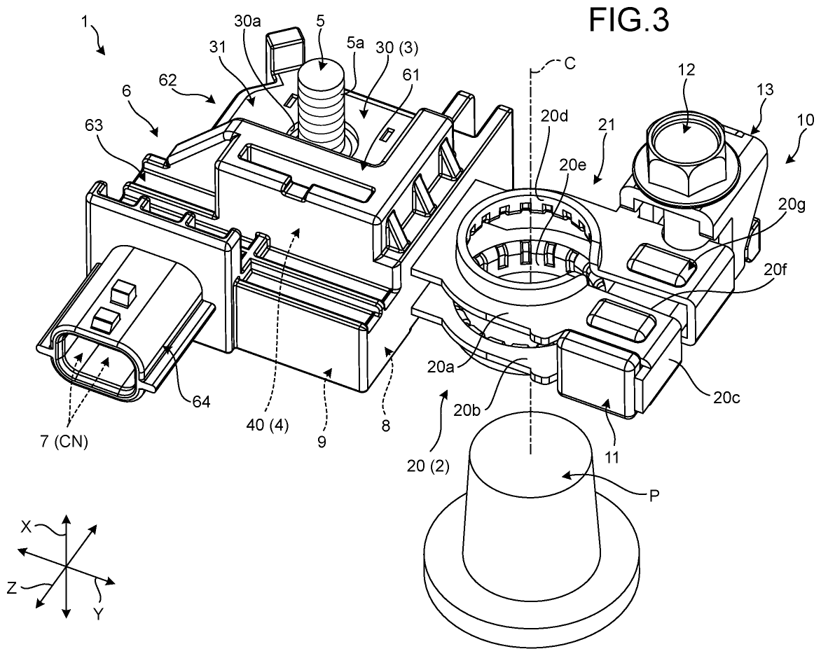

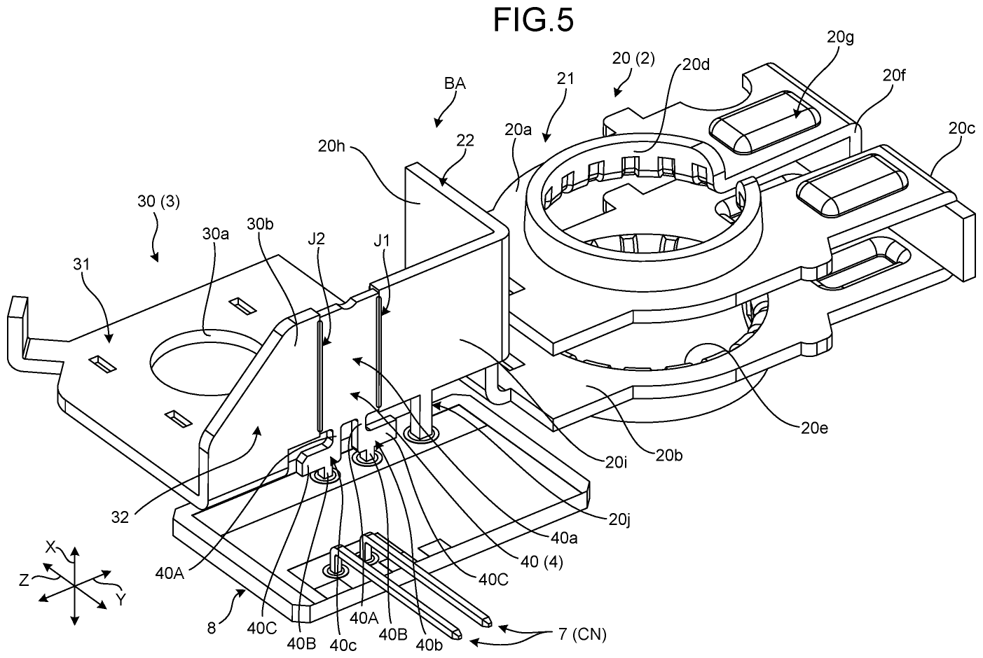

Specifically, as illustrated in FIG. 2, FIG. 3, FIG. 4, and FIG. 5, the current sensor 1 includes the battery terminal unit 2, a terminal connection unit 3, a sensor unit 4, a stud bolt 5, the housing 6, an output terminal 7, a circuit board 8, a mold material 9, and a tightening mechanism 10.

The battery terminal unit 2, the terminal connection unit 3, and the sensor unit 4 integrally constitute a bus bar assembly BA. In other words, it can be said that the current sensor 1 includes the bus bar assembly BA. The bus bar assembly BA includes a BT bus bar 20, a GND bus bar 30, and the shunt resistor 40, and these are integrally configured. The BT bus bar 20 is a first bus bar that constitutes the battery terminal unit 2. The GND bus bar 30 is a second bus bar that constitutes the terminal connection unit 3. The BT bus bar 20 and the GND bus bar 30 form a pair of conductive bus bars in the current sensor 1, and the shunt resistor 40 is conductively connected between the pair of bus bars. The shunt resistor 40 is a resistor for current detection that is conductively connected to the BT bus bar 20 and the GND bus bar 30 and constitutes the sensor unit 4.

Each of the BT bus bar 20, the GND bus bar 30, and the shunt resistor 40 is a plate-shaped metal conductor having conductivity. The BT bus bar 20, the GND bus bar 30, and the shunt resistor 40 are subjected to various types of processing to be formed into shapes corresponding to the battery terminal unit 2, the terminal connection unit 3, and the sensor unit 4, respectively. The BT bus bar 20 and the GND bus bar 30 are made of a metal having high conductivity, for example, copper (Cu) or a copper alloy.

The shunt resistor 40 is made of a dissimilar metal different from the BT bus bar 20 and the GND bus bar 30, for example, a copper-manganese-nickel (Cu—Mn—Ni) alloy, a copper-nickel (Cu—Ni) alloy, a nickel-chromium (Ni—Cr) alloy, and the like with good temperature characteristics as well as resistance values not easily varying depending on temperature.

The battery terminal unit 2 is a conductive part that is fastened to the battery post P, and is composed of the aforementioned BT bus bar 20. The battery terminal unit 2 includes a body section 21 and an electrode section 22. In the battery terminal unit 2, for example, the body section 21 and the electrode section 22 are integrally formed by performing press bending and the like on the BT bus bar 20.

The body section 21 is a main part fastened to the battery post P. The body section 21 includes a pair of plate-shaped parts 20a and 20b each formed in a plate shape, and a bent connection part 20c that connects the plate-shaped parts 20a and 20b. The body section 21 is formed in a state of being folded back in a substantially U shape as a whole with the bent connection part 20c interposed therebetween, and is in a state in which the plate-shaped part 20a and the plate-shaped part 20b face each other at intervals along the axial direction X and are stacked substantially in parallel. In the body section 21, the pair of plate-shaped parts 20a and 20b are provided with post insertion holes 20d and 20e, respectively. Furthermore, in the body section 21, a slit (gap) 20f is formed over the pair of plate-shaped parts 20a and 20b and the bent connection part 20c. In the body section 21, at the ends of the pair of plate-shaped parts 20a and 20b on the bent connection part 20c side, a portion where the slit 20f is formed constitutes a tightening end 20g to be tightened by the tightening mechanism 10.

The electrode section 22 is a part that is juxtaposed with the body section 21 along the first width direction Y and to which the shunt resistor 40 is joined. The electrode section 22 is integrally formed with one of the pair of plate-shaped parts 20a and 20b, here, the plate-shaped part 20b located on the battery B side, and is brought into conduction with the plate-shaped part 20b. The electrode section 22 includes an extending part 20h and a joining piece part 20i that are formed in a plate shape. The plate thickness direction of the extending part 20h is along the first width direction Y, and the extending part 20h extends along the axial direction X and the second width direction Z and is connected to the plate-shaped part 20b on one side (battery B side) in the axial direction X. The plate thickness direction of the joining piece part 20i is along the second width direction Z, and the joining piece part 20i extends along the axial direction X and the first width direction Y and is connected to the extending part 20h on one side (body section 21 side) in the first width direction Y. The joining piece part 20i constitutes an end of the BT bus bar 20 conductively connected to the shunt resistor 40. Furthermore, the electrode section 22 has a detection terminal part 20j that protrudes from the joining piece part 20i along the axial direction X. The detection terminal part 20j is a voltage detection terminal that performs output for detecting a battery voltage that is a voltage of the battery B. The detection terminal part 20j outputs a voltage (potential) that is generated in the joining piece part 20i according to a current flowing through the joining piece part 20i. The detection terminal part 20j is formed in a tab shape (columnar shape) by protruding from an end surface on one side of the joining piece part 20i in the axial direction X to one side (battery B side) along the axial direction X.

The terminal connection unit 3 is a conductive part to which the connection terminal T is electrically connected, and is composed of the aforementioned GND bus bar 30. The terminal connection unit 3 is juxtaposed with the battery terminal unit 2 at intervals along the first width direction Y, and includes a fastening part 31 and an electrode part 32. In the terminal connection unit 3, for example, the fastening part 31 and the electrode part 32 each formed in a plate shape are integrally formed by performing press bending and the like on the GND bus bar 30.

The plate thickness direction of the fastening part 31 is along the axial direction X, and the fastening part 31 extends along the first width direction Y and the second width direction Z. The plate thickness direction of the electrode part 32 is along the second width direction Z, and the electrode part 32 extends along the axial direction X and the first width direction Y, and is connected to the fastening part 31 on one side (battery B side) in the axial direction X. The fastening part 31 is a part to which the connection terminal T is fastened and electrically connected, and is provided with a bolt insertion hole 30a. In the stud bolt 5, in a state in which a shaft 5a is inserted into the bolt insertion hole 30a and the connection terminal T is assembled, a nut 5b is screwed into the shaft 5a to fasten the fastening part 31 and the connection terminal T for conductive connection. The fastening part 31 is electrically connected to the ground part GND and the like via the stud bolt 5, the connection terminal T, and the like, so that the GND bus bar 30 is grounded. The electrode part 32 constitutes a joining piece part 30b of the GND bus bar 30. The joining piece part 30b constitutes an end of the GND bus bar 30 that is conductively connected to the shunt resistor 40. The joining piece part 30b and the aforementioned joining piece part 20i are juxtaposed at intervals along the first width direction Y, and constitute parts to which the shunt resistor 40 is joined, respectively.

The sensor unit 4 is a part that is juxtaposed with the battery terminal unit 2 along the first width direction Y, is conductively connected to the battery terminal unit 2, and detects a current. The sensor unit 4 is located between the battery terminal unit 2 and the terminal connection unit 3 along the first width direction Y. The sensor unit 4 of the present embodiment constitutes a shunt-type current sensor unit and includes the aforementioned shunt resistor 40.

The shunt resistor 40 is formed in a plate shape, and conductively connected between a pair of bus bars, here, the BT bus bar 20 constituting the battery terminal unit 2 and the GND bus bar 30 constituting the terminal connection unit 3. The shunt resistor 40 is located between the joining piece part 20i and the joining piece part 30b in a state in which the end surface of the joining piece part 20i of the BT bus bar 20 and the end surface of the joining piece part 30b of the GND bus bar 30 face each other along the first width direction Y. Furthermore, the shunt resistor 40 is joined to the joining piece part 20i and the joining piece part 30b. The shunt resistor 40 is joined to the joining piece part 20i via a joining portion J1 and is conductively connected to the BT bus bar 20 (the battery terminal unit 2). On the other hand, the shunt resistor 40 is joined to the joining piece part 30b via a joining portion J2 and is conductively connected to the GND bus bar 30 (the terminal connection unit 3). In the sensor unit 4, the joining piece part 20i of the BT bus bar 20 forms an electrode on one side (electrode on the negative electrode side of the battery B) to which the shunt resistor 40 is joined. On the other hand, the joining piece part 30b of the GND bus bar 30 forms an electrode on the other side (electrode on the ground part GND side) to which the shunt resistor 40 is joined.

More specifically, the shunt resistor 40 has a body part 40a and detection terminal parts 40b and 40c that protrude from the body part 40a along the axial direction X.

The body part 40a is a part interposed between a pair of bus bars, that is, the BT bus bar 20 and the GND bus bar 30, and constitutes a main part as a resistor. The BT bus bar 20 and the GND bus bar 30 are conductively connected to both ends of the body part 40a in the first width direction Y. More specifically, the body part 40a is formed in a substantially rectangular plate shape, and extends along the axial direction X and the first width direction Y, wherein the plate thickness direction of the body part 40a is along the second width direction Z. Furthermore, both ends of the body part 40a in the first width direction Y are respectively joined to the joining piece part 20i and the joining piece part 30b by various joining means such as laser welding, electron beam welding, and brazing, so that the above joining portions J1 and J2 are formed and conductively connected to each other. That is, the joining portion J1 constitutes a portion that joins the body part 40a and the battery terminal unit 2 for conductive connection on the negative electrode side of the shunt resistor 40. On the other hand, the joining portion J2 constitutes a portion that joins the body part 40a and the terminal connection unit 3 for conductive connection on the ground part GND side of the shunt resistor 40. With such a configuration, the body part 40a is conductively connected to the BT bus bar 20 constituting the battery terminal unit 2 and the GND bus bar 30 constituting the terminal connection unit 3.

The detection terminal parts 40b and 40c are current detection terminals that perform output for detecting the current flowing through the shunt resistor 40, in other words, the charge/discharge current of the battery B, and are provided in pairs. The pair of detection terminal parts 40b and 40c output a voltage (potential difference) generated between the end of the shunt resistor 40 on the joining piece part 20i side and the end of the shunt resistor 40 on the joining piece part 30b side according to the current flowing through the shunt resistor 40. The detection terminal parts 40b and 40c are formed in a tab shape (columnar shape) by protruding from an end surface on one side of the body part 40a in the axial direction X to one side (battery B side) along the axial direction X. The pair of detection terminal parts 40b and 40c are located at intervals from each other along the first width direction Y. The detection terminal part 40b is formed by protruding from the end of the body part 40a on the joining piece part 20i side along the axial direction X. On the other hand, the detection terminal part 40c is formed by protruding from the end of the body part 40a on the joining piece part 30b side along the axial direction X.

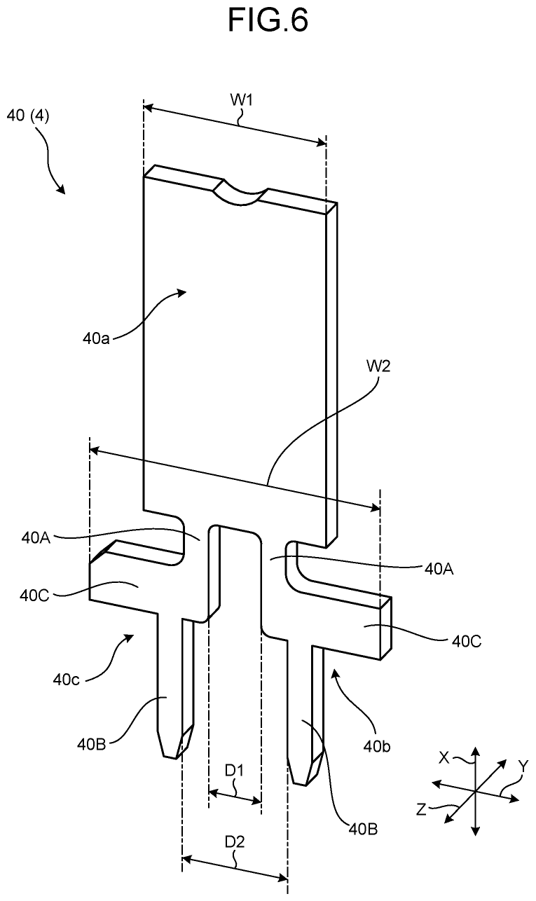

The shapes of the detection terminal parts 40b and 40c are described with reference to FIG. 6 and the like.

The housing 6 is a protective member that has an insulating property and accommodates and protects the sensor unit 4 (the shunt resistor 40), the output terminal 7, the circuit board 8, and the like. The housing 6 is made of, for example, a polyphenylene sulfide (PPS) resin or the like having an insulating property and high heat resistance. Furthermore, the resin such as PPS may contain glass fibers in order to increase the strength of the housing 6. The housing 6 is integrally molded with the bus bar assembly BA, the stud bolt 5, the output terminal 7, and the like by, for example, insert molding and the like, thereafter the circuit board 8 is assembled inside, and then the mold material 9 is provided.

For example, in a state in which the BT bus bar 20, the GND bus bar 30, and the shunt resistor 40 are integrated and the stud bolt 5 is assembled in the bolt insertion hole 30a, the bus bar assembly BA is inserted (set) in a mold for insert molding of the housing 6 together with the output terminal 7. Then, an insulating resin is injected into the mold and molded, so that the housing 6 is integrally formed with the bus bar assembly BA, the stud bolt 5, the output terminal 7, and the like.

The housing 6 accommodates the bus bar assembly BA, the stud bolt 5, and the output terminal 7 therein and exposes part of them to the outside of the housing 6. Specifically, the housing 6 includes a sensor cover part 61, a bolt holding part 62, a board cover part 63, and a connector housing part 64, and these are integrally formed.

The sensor cover part 61 is a part in which the shunt resistor 40 constituting the sensor unit 4 is embedded, and covers and protects the shunt resistor 40. Most of the shunt resistor 40 is embedded in the sensor cover part 61, and a part of the detection terminal parts 40b and 40c is exposed to the outside of the sensor cover part 61 as described later. Furthermore, the entire electrode section 22, the entire electrode part 32 of the terminal connection unit 3, and the joining portions J1 and J2 are also embedded in the sensor cover part 61 together with the shunt resistor 40, and the sensor cover part 61 covers and protects them. The sensor cover part 61 is formed in a substantially L shape according to a series of shapes of the electrode section 22, the shunt resistor 40, and the electrode part 32 when viewed along the axial direction X.

The bolt holding part 62 is a part in which the stud bolt 5 inserted into the bolt insertion hole 30a of the terminal connection unit 3 is embedded and held. The bolt holding part 62 is provided at a position inside the sensor cover part 61 formed in a substantially L shape, and is provided with a step difference with respect to the sensor cover part 61 along the axial direction X. The bolt holding part 62 holds the fastening part 31 and the stud bolt 5 while exposing one surface of the fastening part 31 and the shaft 5a of the stud bolt 5 along one side in the axial direction X.

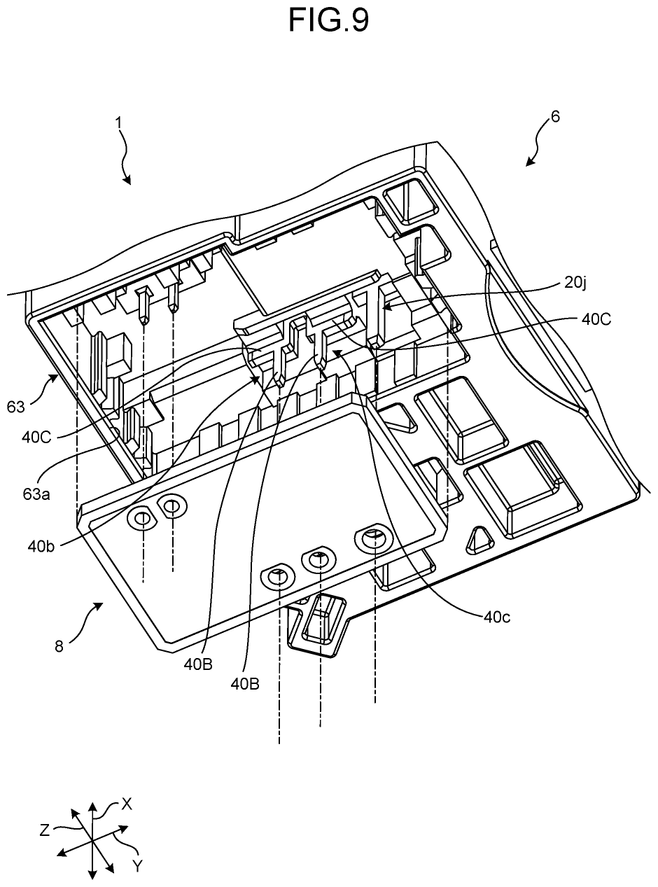

The board cover part 63 is a part that accommodates the circuit board 8 therein and covers and protects the circuit board 8. The board cover part 63 is provided at a position opposite to the bolt holding part 62 with the sensor cover part 61 interposed between the board cover part 63 and the bolt holding part 62 in the second width direction Z, and is provided with a step difference with respect to the sensor cover part 61 along the axial direction X similarly to the bolt holding part 62. An installation opening 63a (see FIG. 9 to be described later) is formed on the board cover part 63, the installation opening 63a is for assembling the circuit board 8 to an inner part of the substrate cover part 63 after molding the housing 6. The installation opening 63a is formed in a substantially rectangular space according to the shape of the circuit board 8, and is opened toward one side (battery B side) in the axial direction X. In the installation opening 63a, the ends of the detection terminal part 20j, the detection terminal parts 40b and 40c, and the output terminal 7 are exposed (see FIG. 9)

The connector housing part 64 is a part that constitutes a connector part CN together with the output terminal 7. The connector housing part 64 is formed by protruding from the board cover part 63 to one side (side opposite to the bolt holding part 62 side) along the second width direction Z. The connector housing part 64 is formed in a cylindrical shape opened on one side in the second width direction Z, and holds the output terminal 7 inside so that the end of the output terminal 7 is exposed.

The output terminal 7 is a terminal that is electrically connected to the circuit board 8 and outputs sensor output detected by the sensor unit 4 to the outside. The output terminal 7 is composed of a pair of bent terminals having conductivity and formed in a substantially L shape. As described above, the output terminal 7 is embedded and integrated inside the connector housing part 64 by insert molding, and constitutes the connector part CN for sensor output together with the connector housing part 64.

In the circuit board 8, electronic components are mounted to form an electronic circuit. The circuit board 8 is composed of, for example, what is called a printed circuit board (PCB). The circuit board 8 is conductively connected to the detection terminal part 20j of the battery terminal unit 2, the detection terminal parts 40b and 40c of the shunt resistor 40, and the output terminal 7. For example, the circuit board 8 is mounted with electronic components for implementing various functions, such as the aforementioned amplifier AP. The circuit board 8 is assembled in the board cover part 63 via the aforementioned installation opening 63a (see FIG. 9). Thereafter, the installation opening 63a is filled with the mold material 9 and sealed by the mold material 9. The mold material 9 is made of, for example, a urethane resin or the like having an insulating property and a high adhesion property.

A voltage (potential difference) generated at both ends of the shunt resistor 40 is input to the circuit board 8 via the pair of detection terminal parts 40b and 40c connected as described above. Furthermore, a voltage (potential) generated in the joining piece part 20i, in other words, the voltage (potential) of the negative electrode of the battery B is input to the circuit board 8 via the detection terminal part 20j connected as described above. Then, the circuit board 8 may output these input voltages (detection voltages) to a higher ECU via the output terminal 7 (analog output). In such a case, the higher ECU calculates a current value and a battery voltage value on the basis of the input detection voltages. Furthermore, the circuit board 8 may be mounted with a microcomputer as an electronic component, calculate the current value and the battery voltage value by the microcomputer on the basis of the input voltages (detection voltages), and output a detection signal representing the calculated current value and battery voltage value to the higher ECU via the output terminal 7 (digital output).

In a state in which the battery post P is inserted into the post insertion holes 20d and 20e of the battery terminal unit 2, the tightening ends 20g are tightened by the tightening mechanism 10, so that the current sensor 1 configured as described above is fastened to the battery post P. As an example, the tightening mechanism 10 includes a plate nut 11 as a penetrating member, a fastening bolt 12 as a fastening member, and a bracket 13 as a pressing force conversion member. The tightening mechanism 10 tightens the fastening bolt 12 along the axial direction X, thereby generating a force by which the plate nut 11 and the bracket 13 tighten the tightening ends 20g along the second width direction Z in cooperation with each other. As a consequence, the tightening mechanism 10 can reduce the diameters of the post insertion holes 20d and 20e, and fasten the battery terminal unit 2 to the battery post P to achieve conduction. Then, in the current sensor 1, the connection terminal T is assembled to the shaft 5a of the stud bolt 5 and the nut 5b is screwed, so that the connection terminal T is fastened to the shaft 5a and the connection terminal T and the fastening part 31 of the terminal connection unit 3 are brought into conduction with each other.

In such a state, the current sensor 1 detects a current according to output from the detection terminal parts 40b and 40c of the shunt resistor 40. That is, the current sensor 1 detects a current flowing between the connection terminal T and the battery post P by the sensor unit 4, and outputs the detected sensor output to the higher ECU via the connector part CN. The current sensor 1 amplifies, by the amplifier AP, a voltage (detection voltage) generated across the shunt resistor 40 according to the current flowing through the shunt resistor 40, outputs the amplified voltage, and detects the current flowing through the shunt resistor 40 on the basis of the output of the amplifier AP. In such a case, a main part that actually calculates a current value may be the microcomputer mounted on the circuit board 8, or the higher ECU that is an output destination of sensor output. Furthermore, the current sensor 1 can also detect a battery voltage according to output from the detection terminal part 20j of the battery terminal unit 2.

Furthermore, in the configuration in which the shunt resistor 40 is built in the housing 6 as described above, the detection terminal parts 40b and 40c of the shunt resistor 40 are formed in a predetermined shape, so that the current sensor 1 of the present embodiment can appropriately perform insert molding of the housing 6.

Specifically, as illustrated in FIG. 4, FIG. 5, and FIG. 6, each of the detection terminal parts 40b and 40c includes a body connection portion 40A, a tip end connection portion 40B, and an intermediate portion 40C. Each of the detection terminal parts 40b and 40c extends along the axial direction X, and is located in the order of the body connection portion 40A, the intermediate portion 40C, and the tip end connection portion 40B from the body part 40a side. The body connection portion 40A, the tip end connection portion 40B, and the intermediate portion 40C are each provided in pairs for the pair of detection terminal parts 40b and 40c at intervals along the first width direction Y.

The body connection portion 40A is a portion of each of the detection terminal parts 40b and 40c, which is connected to the body part 40a. That is, the body connection portion 40A constitutes a base end of each of the detection terminal parts 40b and 40c. The body connection portion 40A is formed in a substantially rectangular columnar shape along the axial direction X.

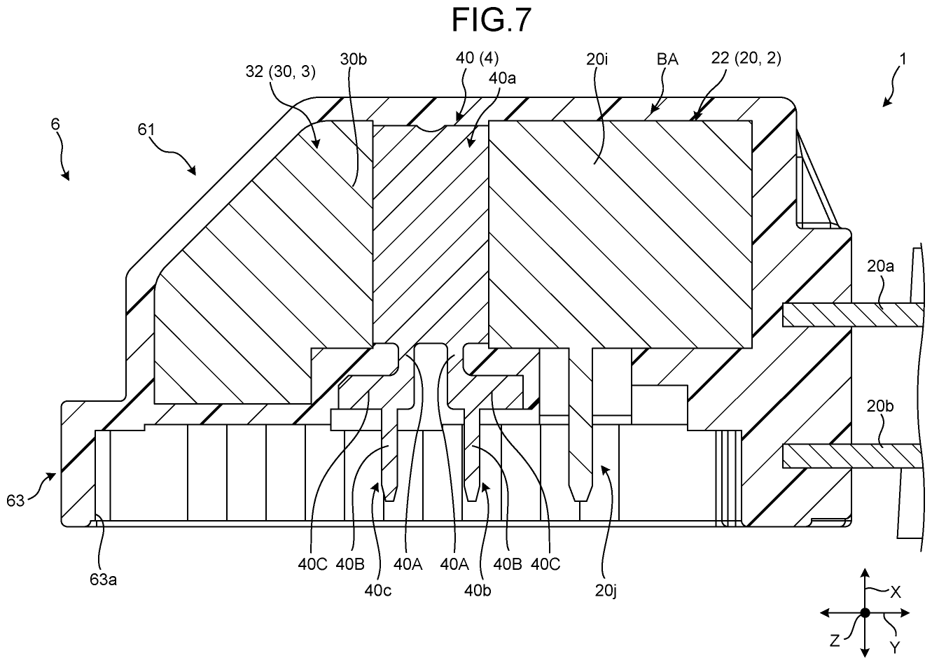

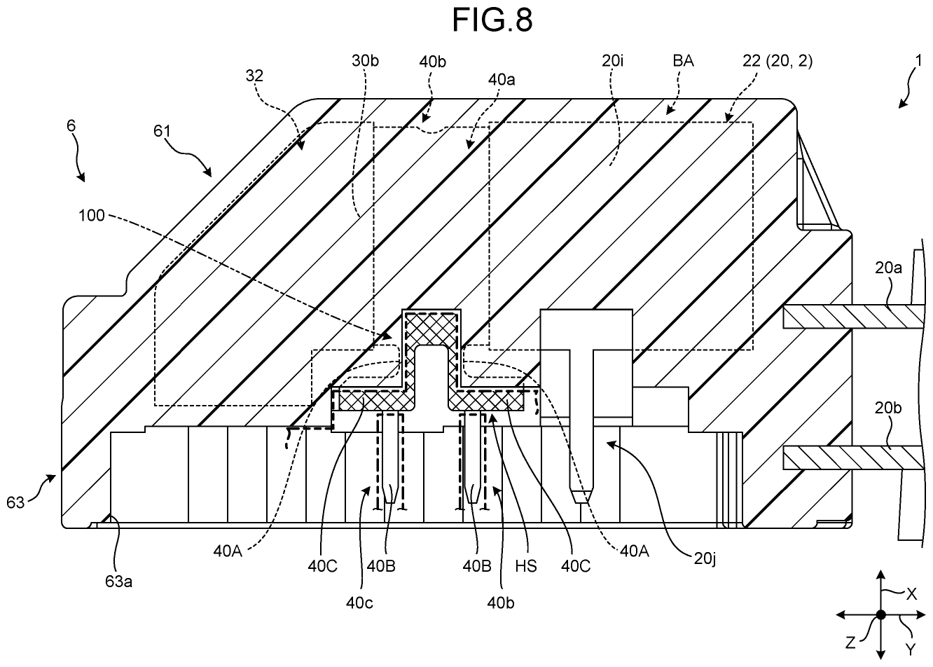

The tip end connection portion 40B is a portion of each of the detection terminal parts 40b and 40c, which is exposed from the housing 6 and extends along the axial direction X (see also FIG. 7, FIG. 8, and FIG. 9). That is, the tip end connection portion 40B constitutes a tip end of each of the detection terminal parts 40b and 40c. The tip end connection portion 40B of the present embodiment constitutes a board mounting portion conductively connected to the circuit board 8 via a solder or the like. The tip end connection portion 40B is formed in a substantially rectangular columnar shape and a tapered shape along the axial direction X.

The intermediate portion 40C is a portion of each of the detection terminal parts 40b and 40c, which is interposed between the body connection portion 40A and the tip end connection portion 40B with respect to the axial direction X and extends by protruding from the tip end connection portion 40B along the first width direction Y. The pair of intermediate portions 40C extends by protruding from the tip end connection portions 40B in a direction away from each other along the first width direction Y, respectively. The intermediate portion 40C is formed in a substantially rectangular beam shape along the first width direction Y.

The shunt resistor 40 of the present embodiment is formed so that the body part 40a, the body connection portion 40A, the tip end connection portion 40B, and the intermediate portion 40C satisfy the following dimensional relation.

That is, the shunt resistor 40 of the present embodiment is provided with the pair of body connection portions 40A and the pair of tip end connection portions 40B so that an interval D1 between the pair of body connection portions 40A along the first width direction Y is equal to or less than an interval D2 between the pair of tip end connection portions 40B along the first width direction Y (D1≤D2). The interval D1 here is narrower than the interval D2 (D1<D2). The interval D1 corresponds to the length along the first width direction Y between the inner end surfaces of the pair of body connection portions 40A facing each other along the first width direction Y. The interval D2 corresponds to the length along the first width direction Y between the inner end surfaces of the pair of tip end connection portions 40B facing each other along the first width direction Y.

Furthermore, the shunt resistor 40 of the present embodiment is provided with the body part 40a and the pair of intermediate portions 40C so that a width W2 of the pair of intermediate portions 40C along the first width direction Y is wider than a width W1 of the body part 40a along the first width direction Y (W2>W1). The width W1 corresponds to the length along the first width direction Y between the end surfaces of the body part 40a in the first width direction Y. The width W2 corresponds to the length along the first width direction Y between the outer end surfaces of the pair of intermediate portions 40C opposite to the inner end surfaces of the pair of intermediate portions 40C facing each other along the first width direction Y. That is, the intermediate portions 40C of the present embodiment protrude more than the body part 40a does along the first width direction Y. Furthermore, the inner end surfaces of the intermediate portions 40C facing each other along the first width direction Y are linearly continuous with the inner end surfaces of the body connection portions 40A along the axial direction X, respectively.

As illustrated in FIG. 7, FIG. 8, and FIG. 9, in the intermediate portion 40C of the present embodiment, a portion of the intermediate portion 40C on the tip end connection portion 40B side is exposed from the housing 6 together with the tip end connection portion 40B, and the other portion of the intermediate portion 40C is built in the housing 6. The portion of the intermediate portion 40C exposed from the housing 6 corresponds to a region that becomes a contact surface HS (shaded region in FIG. 8) with a mold 100 for insert molding during insert molding of the housing 6 as illustrated in FIG. 8. In other words, the portion of the intermediate portion 40C on the tip end connection portion 40B side becomes the contact surface HS with the mold 100, and is exposed from the housing 6 after the insert molding of the housing 6. The contact surface HS extends along the first width direction Y at the end of the intermediate portion 40C on the tip end connection portion 40B side, and is also formed at the end of the body connection portion 40A and the end of the body part 40a. That is, the end of the body connection portion 40A and the end of the body part 40a are also exposed from the housing 6 together with a part of the intermediate portion 40C and the tip end connection portion 40B after the insert molding of the housing 6. On the other hand, other portions of the body part 40a, the intermediate portion 40C, and the body connection portion 40A of the shunt resistor 40, other than the above contact surface HS, are built in the housing 6, and for example, a resin for forming the housing 6 also enters a region between the body part 40a and the intermediate portion 40C, and the like.

The above exposed portions of the shunt resistor 40 are exposed from the housing 6, but are covered with the mold material 9 as described above and are not exposed to the outside in the final form of the current sensor 1. In such a case, in the current sensor 1, in the state in which the exposed portions of the shunt resistor 40 are exposed from the housing 6 to the installation opening 63a side as described above, the mold material (potting material) 9 softer than the housing 6 is filled in the installation opening 63a, which makes it possible to relieve stress applied to the exposed portions. Furthermore, in the current sensor 1, the exposed portions are covered with the mold material 9 as described above, which makes it possible to suppress stress applied to the exposed portions during thermal expansion and contraction and to extend the life of the connection portion between the shunt resistor 40 and the circuit board 8 and the solder.

The current sensor 1 described above can detect a current according to output from the detection terminal parts 40b and 40c of the shunt resistor 40 conductively connected between the pair of BT bus bar 20 and GND bus bar 30 and built in the housing 6. In such a configuration, each of the detection terminal parts 40b and 40c includes the body connection portion 40A connected to the body part 40a of the shunt resistor 40, the tip end connection portion 40B exposed from the housing 6, and the intermediate portion 40C that is interposed between the body connection portion 40A and the tip end connection portion 40B and extends by protruding from the tip end connection portion 40B. With such a configuration, the current sensor 1 can appropriately perform insert molding of the housing 6 in the configuration in which the shunt resistor 40 is built in the housing 6 as described above.

The shunt resistor 40 is typically joined to the BT bus bar 20 and the GND bus bar 30 at the joining portions J1 and J2 by various types of welding as described above. In such a case, since butt portions between the shunt resistor 40 and the BT bus bar 20/GND bus bar 30 are melted during welding, the dimensions of peripheral portions of the joining portions J1 and J2 are contracted. The dimensional contraction of the peripheral portions of the joining portions J1 and J2 during welding tends to have a relatively large variation. Therefore, in order to allow variation in the dimensional contraction, it is necessary to set a clearance between the mold 100 used for insert molding of the housing 6 and the tip end connection portions 40B of the detection terminal parts 40b and 40c.

Based on such a premise, in each of the detection terminal parts 40b and 40c of the shunt resistor 40 of the present embodiment, the intermediate portion 40C protruding from the tip end connection portion 40B is interposed between the body connection portion 40A and the tip end connection portion 40B. With such a configuration, the shunt resistor 40 can secure the contact surface HS with the mold 100 with a sufficient area in the intermediate portion 40C. As a consequence, when the housing 6 is insert-molded, the current sensor 1 can use the contact surface HS of the intermediate portion 40C as a region where resin burr (portion where molten resin flows out into the gap of the mold 100 and is solidified) is generated. With this, even when the clearance is set between the mold 100 and the tip end connection portions 40B as described above, the current sensor 1 can prevent resin from flowing out to the clearance side by the contact surface HS of the intermediate portion 40C. As a consequence, the current sensor 1 can prevent resin burr from being generated on the tip end connection portion 40B side of each of the detection terminal parts 40b and 40c due to the clearance, and can appropriately secure conduction performance of the tip end connection portion 40B. That is, even when the shunt resistor 40 is joined to the BT bus bar 20 and the GND bus bar 30 and then is insert-molded into the housing 6, the current sensor 1 can secure appropriate conduction performance at the tip end connection portions 40B of the detection terminal parts 40b and 40c.

Furthermore, in the shunt resistor 40 of the present embodiment, the intermediate portion 40C is interposed between the body connection portion 40A and the tip end connection portion 40B, so that the interval D1 between the pair of body connection portions 40A and the interval D2 between the pair of tip end connection portions 40B are not restricted with each other. As a consequence, the shunt resistor 40 can be designed with a high degree of freedom and its versatility can be improved.

As described above, the current sensor 1 can appropriately implement a configuration in which the shunt resistor 40 is built in the housing 6.

In the current sensor 1 described above, a portion of the intermediate portion 40C on the tip end connection portion 40B side is exposed from the housing 6 together with the tip end connection portion 40B, and the other portion of the intermediate portion 40C is built in the housing 6. In other words, in the current sensor 1, the exposed portion of the intermediate portion 40C on the tip end connection portion 40B side serves as the contact surface HS with the mold 100 described above, and then the boundary of the housing 6 is located at the intermediate portion 40C. As a consequence, as described above, the current sensor 1 can reliably prevent resin burr from being generated on the tip end connection portion 40B side of each of the detection terminal parts 40b and 40c, and appropriately implement a configuration in which the shunt resistor 40 is built in the housing 6.

Furthermore, in the current sensor 1 described above, the intermediate portion 40C protrudes more than the body part 40a does along the first width direction Y. With such a configuration, the current sensor 1 can secure the contact surface HS with the mold 100 with a sufficient area in the intermediate portion 40C, and make the width W1 of the body part 40a narrower than the width W2 of the intermediate portions 40C. In other words, the current sensor 1 can suppress the size of the body part 40a itself to be small compared to a case where the entire body part 40a is enlarged without providing the intermediate portions 40C and the contact surface HS is secured in the body part 40a. As a consequence, the current sensor 1 can appropriately implement a configuration in which the shunt resistor 40 is built in the housing 6 as described above, and then suppress the manufacturing cost by suppressing an increase in the size of the shunt resistor 40 and suppressing the amount of material used. In addition, the current sensor 1 can make the body part 40a of the shunt resistor 40, which constitutes a main part as a resistor, relatively small, thereby suppressing heat generated in the body part 40a at the time of current detection.

Furthermore, in the current sensor 1 described above, the interval D1 between the pair of body connection portions 40A is narrower than the interval D2 between the pair of tip end connection portions 40B. That is, the current sensor 1 can set the interval D2 between the pair of tip end connection portions 40B as an interval according to a connection target by using the high degree of freedom in design due to the provision of the intermediate portion 40C, and reduce the interval D1 between the pair of body connection portions 40A without being restricted by the interval D2. For example, the interval D1 can be set as a minimum value in a moldable range regardless of the interval D2. Furthermore, the [width W1 of the body part 40a of the shunt resistor 40] can be set as a length of about [interval D1 (minimum value in the moldable range)+width of the body connection portion 40A+welding margin of joining portions J1 and J2], for example. Then, the current sensor 1 can allow the interval D2 between the pair of tip end connection portions 40B to have a degree of freedom according to a connection target. As a consequence, the current sensor 1 can reduce the size of the body part 40a without being restricted by the interval D2 between the pair of tip end connection portions 40B. With this, the current sensor 1 can suppress an increase in the size of the shunt resistor 40, suppress the amount of material used, and suppress the manufacturing cost as described above, and suppress heat generated in the body part 40a.

Furthermore, the current sensor 1 described above includes the circuit board 8 conductively connected to the tip end connection portions 40B. In such a case, for soldering to the circuit board 8, the interval D2 between the pair of tip end connection portions 40B needs to secure a length corresponding to a minimum land diameter that can be manufactured, a distance between lands, and the like according to the circuit board 8 that is a connection target. With respect to this, the current sensor 1 can reduce the interval D1 between the pair of body connection portions 40A without being restricted by the interval D2 between the pair of tip end connection portions 40B as described above. As a consequence, the current sensor 1 can secure a configuration in which the tip end connection portions 40B can be appropriately connected to the circuit board 8, and reduce the size of the body part 40a. With this, the current sensor 1 can suppress an increase in the size of the shunt resistor 40, suppress the amount of material used, and suppress the manufacturing cost as described above, and suppress heat generated in the body part 40a.

Note that the current sensor according to an embodiment of the present invention described above is not limited to the embodiment described above, and various changes can be made within the scope of the claims.

In the above description, the battery terminal unit 2 has a configuration in which the pair of plate-shaped parts 20a and 20b and the bent connection part 20c are integrally formed with each other by press bending of a conductive metal plate, or the like; however, the present invention is not limited thereto. For example, the battery terminal unit 2 may have a configuration in which the bent connection part 20c is not provided, the pair of plate-shaped parts 20a and 20b formed separately from each other are caused to have a 2-layer divided structure, and then the pair of plate-shaped parts 20a and 20b formed separately are integrated.

In the above description, the tightening mechanism 10 constitutes a top-tightening-type mechanism; however, the present invention is not limited thereto. The tightening mechanism 10 may include, for example, a bolt and a nut, and have a lateral tightening-type mechanism in which the tightening ends 20g are tightened along the second width direction Z by tightening the bolt along the second width direction Z.

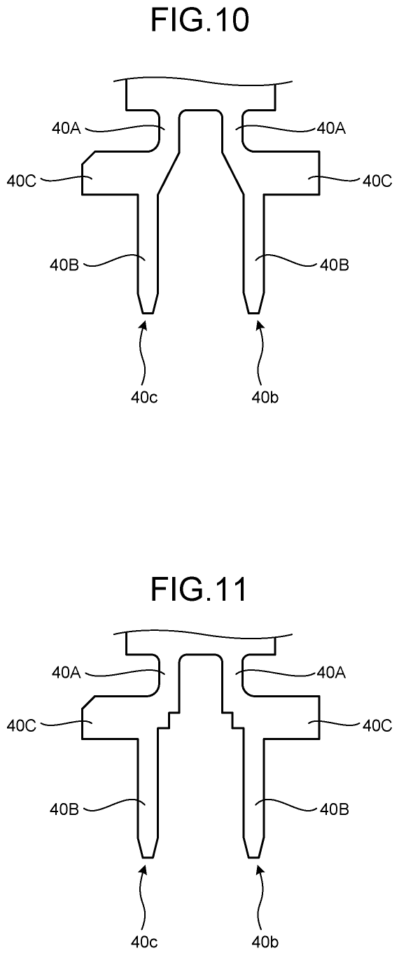

In the above description, the inner end surface of the intermediate portion 40C of each of the detection terminal parts 40b and 40c is linearly continuous with the inner end surface of the body connection portion 40A along the axial direction X; however, the present invention is not limited thereto. For example, as illustrated in FIG. 10, the inner end surface of the intermediate portion 40C may be formed to be inclined with respect to the axial direction X and the first width direction Y so that its inner end surface connects the inner end surface of the body connection portion 40A and the inner end surface of the tip end connection portion 40B. Furthermore, as illustrated in FIG. 11, the inner end surface of the intermediate portion 40C may be formed to have a shape having a plurality of stepped portions so that its inner end surface connects the inner end surface of the body connection portion 40A and the inner end surface of the tip end connection portion 40B.

In the above description, the interval D1 between the pair of body connection portions 40A along the first width direction Y is narrower than the interval D2 between the pair of tip end connection portions 40B along the first width direction Y; however, the present invention is not limited thereto. The interval D1 may be equal to the interval D2, or may be greater than the interval D2 according to occasions.

Similarly, the width W2 of the pair of intermediate portions 40C along the first width direction Y is wider than the width W1 of the body part 40a along the first width direction Y; however, the present invention is not limited thereto. It is sufficient if the width W2 is set within a range in which the contact surface HS with the mold 100 can be secured with a sufficient area in the intermediate portion 40C. Furthermore, the width W1 may be equal to the width W2, or may be greater than the width W2 according to occasions.

In the above description, the tip end connection portion 40B side of each of the detection terminal parts 40b and 40c constitutes a board mounting portion conductively connected to the circuit board 8 via a solder or the like; however, a connection target is not limited to the circuit board 8 and may be a terminal of a connector, or the like.

In the above description, the current sensor 1 is mounted in the vehicle V and constitutes a battery terminal integrated sensor; however, the present invention is not limited thereto. The current sensor 1 may be applied to other objects than the vehicle V, and may not be the battery terminal integrated sensor.

As illustrated in FIG. 5 and the like, the shunt resistor 40 described above is vertically installed substantially perpendicular to the main surface of the circuit board 8 so that the body part 40a and the detection terminal parts 40b and 40c are along the normal direction (the axial direction X) of the main surface (mounting surface) of the circuit board 8; however, the present invention is not limited thereto. For example, the shunt resistor 40 may be disposed to be bent substantially vertically at the body connection portions 40A of the detection terminal parts 40b and 40c so that the body part 40a and the main surface of the circuit board 8 are substantially parallel to each other. In such a case, it is sufficient if the detection terminal parts 40b and 40c have shapes that protrude from the body part 40a along a direction intersecting the axial direction X and are bent at the body connection portions 40A along the axial direction X, and at least the tip end connection portions 40B have a shape that extends along the axial direction X. Furthermore, in such a case, it is sufficient if the BT bus bar 20 and the GND bus bar 30 have shapes according to the arrangement of the shunt resistor 40.

The current sensor according to the present embodiment may also be configured by appropriately combining the components of the embodiment described above and modifications.

### Reference Example

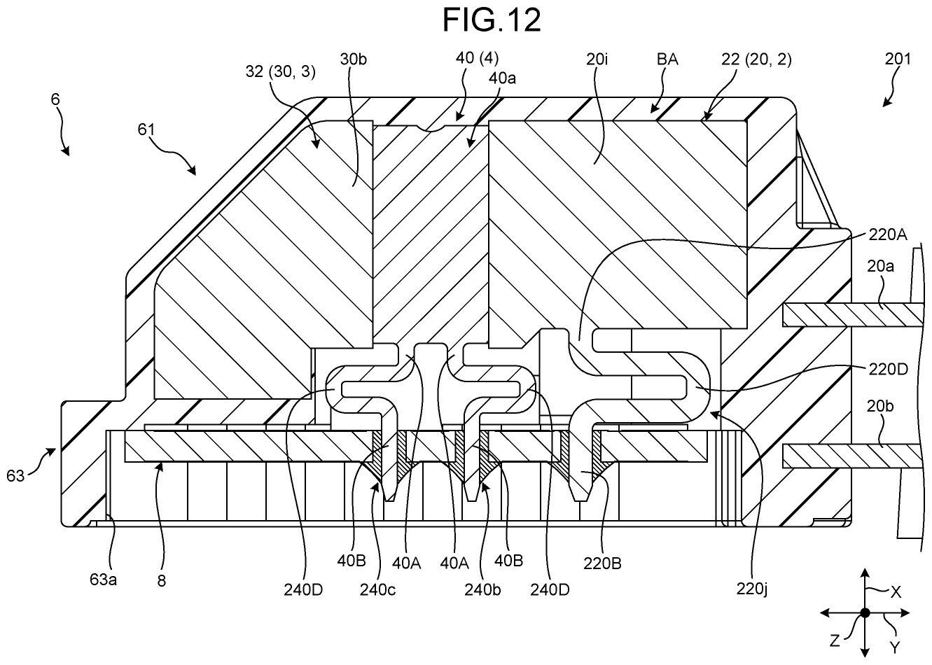

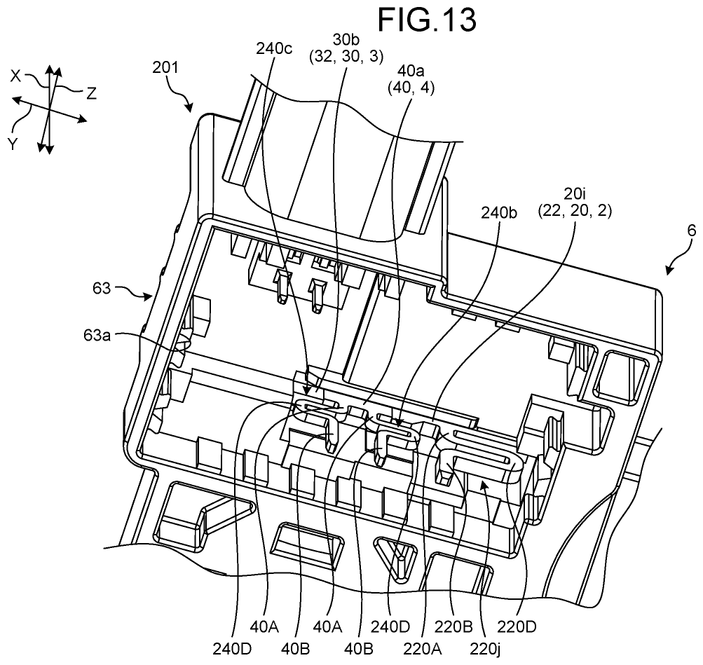

FIG. 12 and FIG. 13 are views illustrating a schematic configuration of a current sensor 201 according to a reference example.

In the current sensor 1 configured as described above, the housing 6 and a resin material such as the mold material 9 are interposed between the bus bar assembly BA including the shunt resistor 40 and the like and the circuit board 8 as described above. The linear expansion coefficient of the current sensor 1 differs greatly between the metal material constituting the bus bar assembly BA and the resin material constituting the housing 6, the mold material 9, and the like.

In such a configuration, for example, the current sensor 1 has room for further improvement in terms of relaxation of stress that may be generated at the connection portions between the circuit board 8 and the detection terminal parts 20j, 40b, and 40c due to the influence of heat generated in the shunt resistor 40 and the like at the time of current detection.

The present reference example is made in view of the above circumstances, and an object of the present reference example is to provide the current sensor 201 capable of relieving stress generated at the connection portions between the detection terminal parts 20j, 40b, and 40c and the circuit board 8.

Specifically, the current sensor 201 according to the reference example is different from the aforementioned current sensor 1 in that detection terminal parts 220j, 240b, and 240c are provided instead of the detection terminal parts 20j, 40b, and 40c. The other configurations of the current sensor 201 are substantially the same as the configuration of the aforementioned current sensor 1.

The detection terminal parts 240b and 240c are different from the aforementioned detection terminal parts 40b and 40c in that a stress relieving shape portion 240D is provided instead of the intermediate portion 40C. The other configurations of the detection terminal parts 240b and 240c are substantially the same as the configuration of the aforementioned detection terminal parts 40b and 40c.

Specifically, each of the detection terminal parts 240b and 240c includes the body connection portion 40A, the tip end connection portion 40B, and the stress relieving shape portion 240D. Each of the detection terminal parts 240b and 240c extends along the axial direction X, and is located in the order of the body connection portion 40A, the stress relieving shape portion 240D, and the tip end connection portion 40B from the body part 40a side. Similarly to the above, in each of the detection terminal parts 240b and 240c, the body connection portion 40A is a portion that is connected to the body part 40a. Similarly to the above, in each of the detection terminal parts 240b and 240c, the tip end connection portion 40B is a portion that constitutes a tip end and constitutes a board mounting portion conductively connected to the circuit board 8 via a solder or the like.

Furthermore, in each of the detection terminal parts 240b and 240c, the stress relieving shape portion 240D is a portion that is interposed between the body connection portion 40A and the tip end connection portion 40B and relieves stress generated at connection portions between the detection terminal parts 240b and 240c and the circuit board 8. In each of the detection terminal parts 240b and 240c, the stress relieving shape portion 240D is formed in a shape in which a portion between the body connection portion 40A and the tip end connection portion 40B is bent along the first width direction Y. The stress relieving shape portion 240D is formed in a shape that is bent and meandered in a substantially U shape along the first width direction Y. The stress relieving shape portion 240D of the detection terminal part 240b and the stress relieving shape portion 240D of the detection terminal part 240c are bent in a direction away from each other along the first width direction Y.

Due to such a shape, the stress relieving shape portion 240D can absorb, by the above bending shape, relative displacement between the body part 40a and the circuit board 8 along the axial direction X, which is generated due to a difference between linear expansion coefficients of respective components when heat is generated in the shunt resistor 40 or the like due to current detection at the time of current detection. As a consequence, the current sensor 201 can release and relieve, by the stress relieving shape portion 240D, stress generated at the connection portions between the detection terminal parts 240b and 240c and the circuit board 8.

Furthermore, similarly to the detection terminal parts 240b and 240c, the detection terminal part 220j of the present reference example includes a body connection portion 220A, a tip end connection portion 220B, and a stress relieving shape portion 220D. The body connection portion 220A is a portion corresponding to the body connection portion 40A, and is a portion connected to the joining piece part 20i of the BT bus bar 20. The tip end connection portion 220B is a portion corresponding to the tip end connection portion 40B, and is a portion that constitutes a board mounting portion conductively connected to the circuit board 8 via a solder or the like.

Furthermore, the stress relieving shape portion 220D is a portion corresponding to the stress relieving shape portion 240D, and is a portion that is interposed between the body connection portion 220A and the tip end connection portion 220B and relieves stress generated at the connection portion between the detection terminal part 220j and the circuit board 8. Similarly to the stress relieving shape portion 240D, the stress relieving shape portion 220D is formed in a shape in which a portion between the body connection portion 220A and the tip end connection portion 220B is bent along the first width direction Y. The stress relieving shape portion 220D of the detection terminal part 220j is bent in a direction away from the detection terminal part 240b along the first width direction Y.

Due to such a shape, the stress relieving shape portion 220D can absorb, by the above bending shape, relative displacement between the joining piece part 20i and the circuit board 8 along the axial direction X, which is generated due to a difference between linear expansion coefficients of respective components when heat is generated in the shunt resistor 40 or the like due to current detection at the time of current detection. As a consequence, the current sensor 201 can release and relieve, by the stress relieving shape portion 220D, stress generated at the connection portion between the detection terminal part 220j and the circuit board 8.

The current sensor 201 configured as described above can relieve, by the stress relieving shape portions 220D and 240D, stress generated at the connection portions between the detection terminal parts 220j, 240b, and 240c and the circuit board 8 due to repeated expansion and contraction caused by a temperature change due to heat or the like generated in the shunt resistor 40 due to current detection. As a consequence, the current sensor 201 can improve the durability of the connection portions between the detection terminal parts 220j, 240b, and 240c and the circuit board 8, for example.

In the detection terminal parts 220j, 240b, and 240c of the present reference example, the body connection portions 40A and 220A, the tip end connection portions 40B and 220B, and the stress relieving shape portions 240D and 220D are all exposed from the housing 6 (see particularly FIG. 13 and the like). Furthermore, in the current sensor 201 of the present reference example, a region of the end of the body part 40a on the detection terminal parts 240b and 240c side and the end of the joining piece part 20i on the detection terminal part 220j side corresponds to the region serving as the contact surface with the mold for insert molding of the housing 6 as described above. Therefore, the end of the body part 40a on the detection terminal parts 240b and 240c side and the end of the joining piece part 20i on the detection terminal part 220j side are also exposed from the housing 6.

Also in such a case, similarly to the current sensor 1, in the current sensor 201, in a state in which all of the detection terminal parts 220j, 240b, and 240c and the ends of the body part 40a and the joining piece part 20i are exposed from the housing 6 toward the installation opening 63a, the mold material (potting material) 9 softer than the housing 6 is filled in the installation opening 63a, which makes it possible to relieve stress applied to the exposed portions. That is, similarly to the current sensor 1, the detection terminal parts 220j, 240b, and 240c and the like are covered with the mold material 9 as described above and are not exposed to the outside in the final form of the current sensor 201.

In the above description, the tip end connection portions 40B and 220B are conductively connected to the circuit board 8 via a solder or the like; however, the present invention is not limited thereto and the tip end connection portions 40B and 220B may also be conductively connected by brazing, welding, press fitting, or the like.

Furthermore, in the above description, the stress relieving shape portions 240D and 220D are formed in a shape that are bent and meandered in a substantially U shape along the first width direction Y; however, the present invention is not limited thereto and the shape of the stress relieving shape portions 240D and 220D is not limited to the above as long as it absorbs relative displacement between the body part 40a/the joining piece part 20i and the circuit board 8 and relieves stress generated at the connection portions between the detection terminal parts 220j, 240b, and 240c and the circuit board 8. The stress relieving shape portions 240D and 220D may be formed in, for example, a zigzag shape or a bellows shape that is repeatedly and continuously folded along the axial direction X.

A current sensor according to the present embodiment can detect a current according to output from a detection terminal part of a shunt resistor conductively connected between a pair of bus bars and built in a housing. In such a configuration, the detection terminal part includes a body connection portion that is connected to a body part of the shunt resistor, a tip end connection portion that is exposed from the housing, and an intermediate portion that is interposed between the body connection portion and the tip end connection portion and extends by protruding from the tip end connection portion. As a consequence, the current sensor has an effect capable of appropriately implementing the configuration in which the shunt resistor is built in the housing.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A current sensor comprising:
a pair of bus bars having conductivity;
a shunt resistor conductively connected between the pair of bus bars; and
a housing having an insulating property and in which the shunt resistor is built, wherein
the shunt resistor includes a body part interposed between the pair of bus bars and a detection terminal part for current detection that protrude from the body part, and
the detection terminal part includes a body connection portion that is connected to the body part, a tip end connection portion that is exposed from the housing and extends along a first direction, and an intermediate portion that is interposed between the body connection portion and the tip end connection portion and extends by protruding from the tip end connection portion along a second direction intersecting the first direction.

2. The current sensor according to claim 1, wherein
a portion of the intermediate portion on the tip end connection portion side is exposed from the housing together with the tip end connection portion, and the other portion of the intermediate portion is built in the housing.

3. The current sensor according to claim 1, wherein
the intermediate portion protrudes more than the body part does along the second direction.

4. The current sensor according to claim 2, wherein
the intermediate portion protrudes more than the body part does along the second direction.

5. The current sensor according to claim 1, wherein
the body connection portion, the tip end connection portion, and the intermediate portion are each provided in pairs at intervals along the second direction, and
an interval between the pair of body connection portions along the second direction is narrower than an interval between the pair of tip end connection portions along the second direction.

6. The current sensor according to claim 2, wherein
the body connection portion, the tip end connection portion, and the intermediate portion are each provided in pairs at intervals along the second direction, and
an interval between the pair of body connection portions along the second direction is narrower than an interval between the pair of tip end connection portions along the second direction.

7. The current sensor according to claim 3, wherein
the body connection portion, the tip end connection portion, and the intermediate portion are each provided in pairs at intervals along the second direction, and
an interval between the pair of body connection portions along the second direction is narrower than an interval between the pair of tip end connection portions along the second direction.

8. The current sensor according to claim 4, wherein
the body connection portion, the tip end connection portion, and the intermediate portion are each provided in pairs at intervals along the second direction, and
an interval between the pair of body connection portions along the second direction is narrower than an interval between the pair of tip end connection portions along the second direction.

9. The current sensor according to claim 1, further comprising:
a circuit board conductively connected to the tip end connection portion.

10. The current sensor according to claim 2, further comprising:
a circuit board conductively connected to the tip end connection portion.

11. The current sensor according to claim 3, further comprising:
a circuit board conductively connected to the tip end connection portion.

12. The current sensor according to claim 4, further comprising:
a circuit board conductively connected to the tip end connection portion.

13. The current sensor according to claim 5, further comprising:
a circuit board conductively connected to the tip end connection portion.

14. The current sensor according to claim 6, further comprising:
a circuit board conductively connected to the tip end connection portion.

15. The current sensor according to claim 7, further comprising:
a circuit board conductively connected to the tip end connection portion.

16. The current sensor according to claim 8, further comprising:
a circuit board conductively connected to the tip end connection portion.
